(19) United States
(12) Patent Application Publication
(10) Pub. No.: US 2002/0058106 A1
(43) Pub. Date: May 16, 2002

(54) Process for preparing a bis (alkylcyclopentadienyl) ruthenium, bis (alkylcyclopentadienyl) ruthenium prepared thereby, and chemical vapor deposition of a ruthenium film or ruthenium-compound film

(75) Inventors: Koji Okamoto, Kanagawa (JP); Junichi Taniuchi, Kanagawa (JP); Hiroaki Suzuki, Kanagawa (JP)

Correspondence Address: ARENT FOX KINTNER PLOTKIN & KAHN, PLLC, Suite 600, 1050 Connecticut Avenue, Washington, DC, 20036-5339, US

(73) Assignee: TANAKA KIKINZOKU KOGYO K.K.

(21) Appl. No.: 09/923,951

(22) Filed: Aug. 8, 2001

(30) Foreign Application Priority Data
Sep. 26, 2000 (JP) 2000-292288

(51) Int. Cl. C23C 16/06; C07F 17/02

(52) U.S. Cl. 427/250; 556/136

(57) ABSTRACT

A process for preparing a bis(alkylcyclopentadienyl) ruthenium comprising the step of reacting a ruthenium compound having an anion not containing chlorine with an alkylcyclopentadiene in an organic solvent. Particularly preferably, the ruthenium compound as a starting material is selected from ruthenium nitrate, ruthenium sulfate and ruthenium acetate. It is preferable that the reaction system contain zinc as a reducing agent. An appropriate temperature is −80 to 0° C.

### BACKGROUND OF THE INVENTION 1. Field of the Invention

This invention relates to a process for preparing a bis(alkylcyclopentadienyl)ruthenium which is an organometallic compound for preparing a ruthenium or ruthenium oxide film by chemical vapor deposition. This invention also relates to a bis(alkylcyclopentadienyl) ruthenium prepared by the process and a method for manufacturing a ruthenium or ruthenium-compound film using the bis(alkylcyclopentadienyl)ruthenium.

2. Description of the Prior Art

A ruthenium or ruthenium oxide film has been recently investigated as a film electrode material for a semiconductor device such as a DRAM (Dynamic RAM) because these materials have a lower resistivity and exhibit good electric properties when used as an electrode. For the above DRAM, its use as a material for a storage electrode in a capacitor has been studied in expectation of its significant contribution to a higher density. It is expected to become a major material for a film electrode in future.

A ruthenium or ruthenium film has been often produced by, besides sputtering, chemical vapor deposition (hereinafter, referred to as CVD) because CVD may easily provide a uniform film and particularly give a better step coverage (i.e., ability to cover a step) than sputtering. Thus, CVD is believed to become a major process for preparing a film electrode, which can accommodate increasingly high density in electronic components.

A bis(alkylcyclopentadienyl)ruthenium represented by formula 1 has been recently studied as a starting material for preparing a ruthenium and ruthenium oxide film by CVD. The bis(alkylcyclopentadienyl)ruthenium is a derivative of bis(cyclopentadienyl)ruthenium (generally referred to as ruthenocene) where hydrogen atoms in two cyclopentadiene rings are replaced by alkyl groups. The bis(alkylcyclopentadienyl)ruthenium is easily handled because it has sufficiently low boiling point to be a liquid at an ambient temperature. In addition, it is believed to be suitable as a starting material for CVD because it may give an improved efficiency in producing a film owing to its higher vapor pressure.

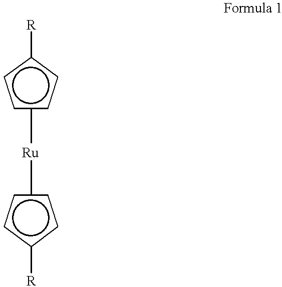

where R represents an alkyl group such as methyl, ethyl and propyl.

In a known process for preparing a bis(alkylcyclopentadienyl) ruthenium, ruthenium trichloride (RuCl₃) and an alkylcyclopentadiene represented by formula 2 are reduced with zinc powder in an alcohol solvent (See JP -A 11-35589 for more details of this preparation process).

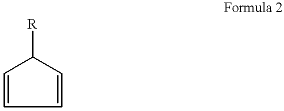

where R represents an alkyl group such as methyl, ethyl and propyl.

However, when preparing a ruthenium film by CVD using a bis(alkylcyclopentadienyl) ruthenium prepared by the known process, a film purity may be acceptable, but a film with inadequate morphology, particularly surface roughness, may be formed. Its surface roughness may be quite small in an order of nanometers, but may be significant in consideration of its application as a film electrode. In particular, demand for larger performance in a semiconductor device has been constantly growing. For a DRAM, studies have been attempting to increase its capacity from M bits to G bits. To achieve such improvement, densification of a device is essential. It is, therefore, needed that morphology in a film electrode is considerably precise.

### BRIEF SUMMARY OF THE INVENTION

This invention has been made in such a background, and an object of this invention is to provide a process for preparing a bis(alkylcyclopentadienyl)ruthenium which can provide a ruthenium or ruthenium film with a higher purity and good morphology.

The inventors have investigated causes of a film formed with defective morphology for a bis(alkylcyclopentadienyl)ruthenium prepared by the conventional process, and have finally found that a bis(alkylcyclopentadienyl)ruthenium prepared by the conventional process contains a quite small amount of an organic ruthenium compound formed by oxidation of the bis(alkylcyclopentadienyl) ruthenium due to its contact with air leading to introduction of oxygen to its alkyl substituent and formation of, for example, a carboxyl, alcohol or ketone moiety.

The inventors have found that such an oxide of the bis(alkylcyclopentadienyl)ruthenium has higher melting and boiling points and a lower vapor pressure than the bis(alkylcyclopentadienyl)ruthenium and is sufficiently stable to be resistant to decomposition. Therefore, when forming a film using the bis(alkylcyclopentadienyl)ruthenium containing these, the impurities might adversely affect a film-forming mechanism such that morphology of the film may be deteriorated.

As described above, a bis(alkylcyclopentadienyl)ruthenium itself is a relatively stable organic compound so that it may not be easily oxidized by brief contact with air. The above investigation results are, therefore, not consistent with the properties of the conventional known bis(alkylcyclopentadienyl)ruthenium. Thus, the inventors have further studied relationship between the conventional preparation process for a bis(alkylcyclopentadienyl)ruthenium and oxidation of a product and have found that in the conventional process, the product bis(alkylcyclopentadienyl)ruthenium contains chlorine derived from ruthenium chloride used as a starting material, which acts as an oxidation catalyst to promote oxidation of the bis(alkylcyclopentadienyl)ruthenium.

From the investigation results, the inventors have concluded that it is necessary to prevent contamination with chlorine capable of accelerating oxidation for providing a bis(alkylcyclopentadienyl)ruthenium which may give a film with good morphology, and have achieved this invention.

Specifically, the invention disclosed herein relates to a process for preparing a bis(alkylcyclopentadienyl) ruthenium represented by formula 5:

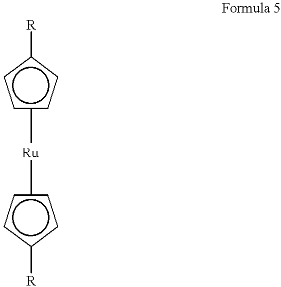

where R represents alkyl such as methyl, ethyl and propyl, comprising the step of reacting a ruthenium compound represented by formula 3:

R u X Formula 3

where X is an anion not containing chlorine, with an alkylcyclopentadiene represented by formula 4:

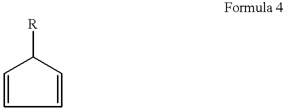

where R is as defined above, in an organic solvent.

In this invention, an alkylcyclopentadiene is reacted with a ruthenium compound free from chlorine in place of ruthenium chloride used in a conventional preparation process. The process of this invention can prepare a chlorine-free bis(alkylcyclopentadienyl) ruthenium because chlorine is not present in the reaction system. A ruthenium compound as a starting material is of course free from chlorine in its anion. Preferred ruthenium compounds free from chlorine in its anion include ruthenium nitrate, ruthenium sulfate, ruthenium acetate, trinitratonitrosyl diaquaruthenium, formatodicarbonyl ruthenium, dodecacarbonyl triruthenium, and tris (acetylacetonato) ruthenium. Particularly preferred ruthenium compounds include ruthenium nitrate, ruthenium sulfate and ruthenium acetate because they are relatively easy to obtain and handle.

As defined in claim 1, a reaction for preparing a bis(alkylcyclopentadienyl)ruthenium is conducted in an organic solvent. An alkylcyclopentadiene reacting with a ruthenium compound is insoluble in water and it is thus preferable to dissolve the materials in an organic solvent for achieving a good reaction efficiency to a bis(alkylcyclopentadienyl) ruthenium. An organic solvent herein is preferably an alcohol. An alcohol is suitable for industrial production of a bis(alkylcyclopentadienyl)ruthenium because it is readily available among organic solvents and has good handling properties without possibility of explosion.

In a process for preparing a bis(alkylcyclopentadienyl)ruthenium according to this invention, it is preferable to add zinc as a reducing agent in a reaction system for ensuring reaction of a ruthenium compound with an alkylcyclopentadiene. Zinc added here is preferably in a form of powder.

Furthermore, the reaction for preparing a bis(alkylcyclopentadienyl)ruthenium is preferably conducted with cooling to −80 to 0° C. If a temperature is higher than 0° C., a side reaction will occur in addition to the reaction providing the desired bis(alkylcyclopentadienyl)ruthenium leading to a reduction in a yield of the bis(alkylcyclopentadienyl)ruthenium whereas if a temperature is below −80° C., a formation efficiency may be reduced due to retardation of the reaction.

In this invention, a reaction is conducted by mixing a ruthenium compound, an alkylcyclopentadiene and optionally zinc in an organic solvent, and there are no restrictions to the adding order of these materials. For example, a ruthenium compound and an alkylcyclopentadiene may be dissolved in an alcohol prior to addition of zinc. In such a case, zinc which is added later is preferably added in portions. If zinc is added in one portion, the reaction will quickly proceed so that a temperature of the reaction system may be excessively elevated to accelerate side reactions, leading to a reduced purity of the bis(alkylcyclopentadienyl)ruthenium.

Alternatively, an alkylcyclopentadiene and zinc may be added to an alcohol before adding a ruthenium compound. In such a case, the ruthenium compound may be added in portions to allow the reaction for producing bis(alkylcyclopentadienyl)ruthenium to gradually proceed, resulting in prevention of contact between the unreacted alkylcyclopentadiene with the ruthenium compound as much as possible and thus inhibition of side reactions. It may be, therefore, concluded that most preferably an alkylcyclopentadiene and zinc are mixed in an alcohol before adding a ruthenium compound for preparing a bis(alkylcyclopentadienyl)ruthenium with the highest purity.

The process described above may eliminate contamination of a product bis(alkylcyclopentadienyl)ruthenium with chlorine and oxidation of the bis(alkylcyclopentadienyl)ruthenium. Furthermore, the bis(alkylcyclopentadienyl) ruthenium prepared by the process is extremely pure without impurities. The bis(alkylcyclopentadienyl) ruthenium prepared by the process of this invention may be, therefore, used to form a ruthenium film with good morphology.

Additionally, the bis(alkylcyclopentadienyl) ruthenium is a useful CVD material from the viewpoint of corrosion of a material for constructing the apparatus. Specifically, a stainless steel is often used as a material constructing a CVD apparatus in view of its corrosivity, but it is known that a stainless steel is susceptible to chlorine and that a small amount of chlorine may cause deposit corrosion and/or stress corrosion cracking. A chlorine-free bis(alkylcyclopentadienyl) ruthenium prepared by the process of this invention may be used to reduce a possibility of shutdown of a apparatus due to its corrosion and allow for a more efficient film forming process.

A CVD process using the bis(alkylcyclopentadienyl) ruthenium may produce a film with good morphology and step coverage. A substrate temperature in the process is preferably 200° C. to 300° C. for decomposing a ruthenium compound. In the CVD process, a reactor is preferably evacuated because evacuation of the reactor may lead to a uniform film-thickness distribution and good step coverage (ability to cover a step). A pressure in the reactor preferably ranges from 140 to 1400 Pa.

Furthermore, a bis(alkylcyclopentadienyl) ruthenium has a property that it can be readily decomposed by introducing oxygen gas into the reaction system. It is, therefore, preferable that a ruthenium compound evaporated in an atmosphere containing oxygen gas is decomposed in a CVD process using the bis(alkylcyclopentadienyl)ruthenium.

### BRIEF DESCRIPTION OF THE DRAWINGS

FIG. 1 shows IR spectra of bis(ethylcyclopentadienyl)ruthenium lots prepared in Embodiments 1 and 2 and Comparative Example; and

FIG. 2 is a schematic view of the CVD apparatus used in Embodiments 1 and 2 and Comparative Example.

### DETAILED DESCRIPTION OF THE PREFERRED EMBODIMENTS

Preferred embodiments of this invention are described together with Comparative Example.

Embodiment 1

This embodiment relates to preparation of bis(ethylcyclopentadienyl)ruthenium, i.e., a bis(alkylcyclopentadienyl)ruthenium in which a substituent is ethyl. In a flask under a nitrogen atmosphere were placed 1750 mL of ethyl alcohol, 212 g of ethylcyclopentadiene and 386 g of zinc powder (purity: 99.999%, 200 mesh), and the mixture was blended. To the mixture at −40° C. was added dropwise 130 g of ruthenium nitrate to cause a reaction and the mixture was stirred at −40° C. for 24 hours. After the reaction, the liquid phase was collected and then extracted with hexane to give 100 g of bis(ethylcyclopentadienyl)ruthenium, which was pale-yellow and transparent.

Embodiment 2

In this embodiment, bis(ethylcyclopentadienyl)ruthenium was prepared using ruthenium acetate in place of ruthenium nitrate in Embodiment 1. In Embodiment 2, the amount of ruthenium acetate used was 130 g, and the other conditions such as the amount of ethylcyclopentadiene and a reaction temperature were as described in Embodiment 1. In this embodiment, there was obtained 99 g of bis(ethylcyclopentadienyl)ruthenium.

### COMPARATIVE EXAMPLE

As a comparative example to Embodiments 1 and 2, bis(ethylcyclopentadienyl)ruthenium was prepared using ruthenium chloride in place of ruthenium nitrate. In this comparative example, 102 g of bis(ethylcyclopentadienyl)ruthenium was obtained as described in Embodiments 1 and 2 except that 130.7 g of ruthenium chloride trihydrate was reacted in place of ruthenium nitrate. It was found that the bis (ethylcyclopentadienyl) ruthenium thus obtained was brown and containing a trace of precipitate.

Chlorine contents of the bis(ethylcyclopentadienyl)ruthenium lots prepared in Embodiments 1 and 2 and Comparative Example 1 were determined to be 4.7 and 4.2 ppm for Embodiments 1 and 2, respectively, while being 24 ppm for Comparative Example. It was, therefore, confirmed that bis(ethylcyclopentadienyl)ruthenium prepared in Comparative Example has a higher chlorine concentration than those in Embodiments 1 and 2.

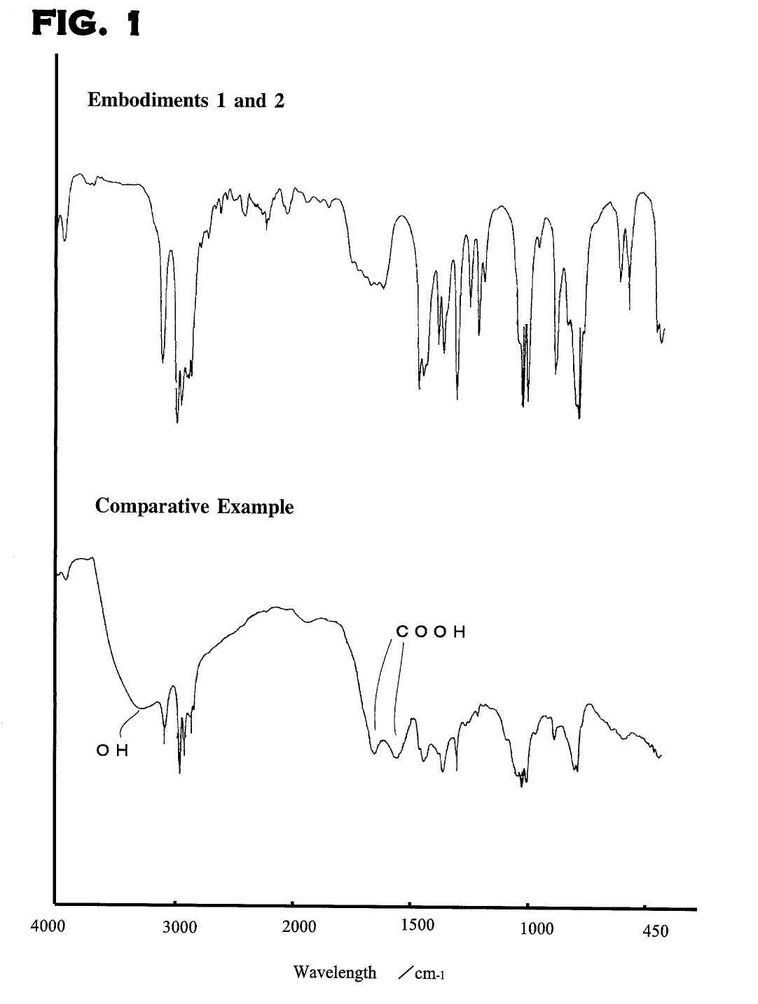

FT-IR analysis (Fourier transform infrared spectroscopy) for these bis(ethylcyclopentadienyl)ruthenium lots gave the profiles as shown in FIG. 1. FIG. 1 shows that the bis(ethylcyclopentadienyl)ruthenium lot prepared in Comparative Example has a peak indicating carboxyl (COOH) generated by partial oxidation. In contrast, the bis(ethylcyclopentadienyl)ruthenium lots prepared in Embodiments 1 and 2 indicate the same spectrum and do not indicate a peak from partial oxidation. The results may indicate that the bis(ethylcyclopentadienyl)ruthenium lot prepared in Comparative Example contained chlorine which acted as a catalyst for air oxidation of the bis(ethylcyclopentadienyl)ruthenium.

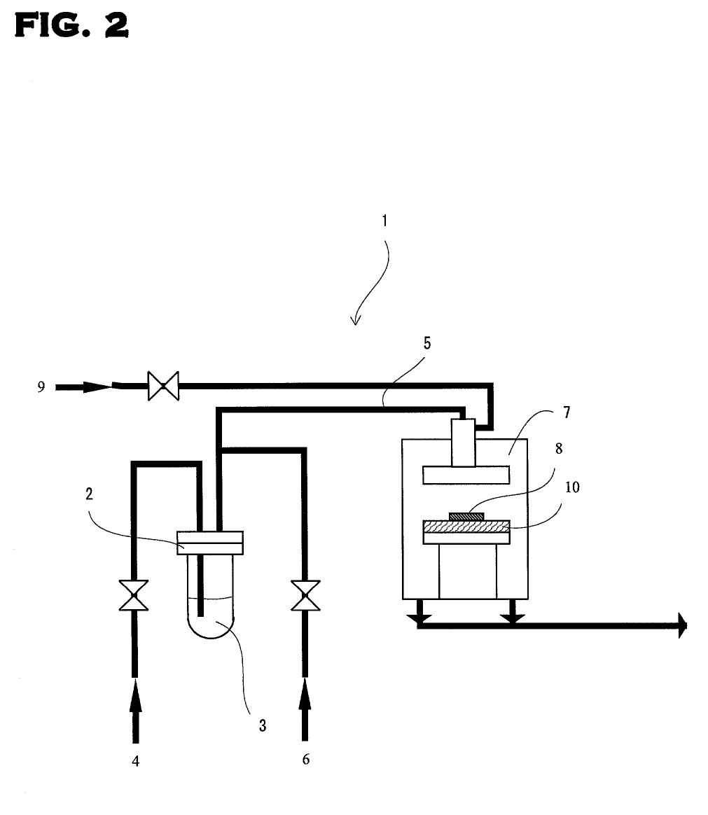

Next, morphology was studied for ruthenium films formed by CVD using the bis(ethylcyclopentadienyl)ruthenium lots prepared in Embodiments 1 and 2 and Comparative Example. The ruthenium films were formed using a CVD apparatus illustrated in FIG. 2. In the CVD apparatus 1 in FIG. 2, bis(ethylcyclopentadienyl)ruthenium 3 charged into a constant-temperature reactor 2 is heated with bubbling argon gas 4 to be a source gas 5, which is then mixed with argon gas 6 as a carrier gas and fed to the surface of a substrate 8 in the chamber 7. In addition, oxygen gas 9 is fed into the chamber 7 as a reactant gas for accelerating decomposition of bis (ethylcyclopentadienyl) ruthenium. The substrate 8 is heated by a heater 10 to cause a CVD film forming reaction on the surface of the substrate. The conditions for this process are as follows.

| | |
|---|---|
| Substrate: | SiO₂/Si |
| Substrate temperature: | 240° C. |
| Chamber pressure: | 666.6 Pa (5.0 Torr) |
| Carrier gas flow rate: | 200 mL/min |
| Oxygen gas flow rate: | 200 mL/min |

Surface roughness of the ruthenium films thus formed was determined using AFM (Atomic Force Microscope). Thus, surface roughness values of the ruthenium films formed from the bis(ethylcyclopentadienyl)ruthenium lots prepared in Embodiments 1 and 2 were Rms=4.1 nm and Rms=4.0 nm, respectively. In contrast, a surface roughness value of the ruthenium film formed from the bis(ethylcyclopentadienyl)ruthenium lot prepared in Comparative Example 1 was Rms=7.8 nm.

In terms of surface roughness of a film formed, the bis(ethylcyclopentadienyl)ruthenium lots from these Embodiments can provide a superior film to that from Comparative Example. Such difference in film appearance may be due to the effect of a bis(alkylcyclopentadienyl) ruthenium oxide present in a source material for film formation; in other words, both Embodiments does not include chlorine which may act as an oxidation catalyst for a bis(alkylcyclopentadienyl)ruthenium.

What is claimed is:

1. A process for preparing a bis(alkylcyclopentadienyl) ruthenium represented by Formula 3: 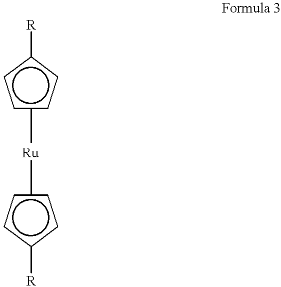
wherein R represents an alkyl group such as methyl, ethyl and propyl, comprising the step of reacting a ruthenium compound represented by Formula 1:
R u X Formula 1
wherein X is an anion not containing chlorine, with an alkylcyclopentadiene represented by Formula 2: 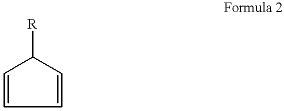
wherein R is as defined above, in an organic solvent.

2. The process for preparing a bis(alkylcyclopentadienyl)ruthenium according to claim 1 wherein the ruthenium compound is selected from the group consisting of ruthenium nitrate, ruthenium sulfate and ruthenium acetate.

3. The process for preparing a bis(alkylcyclopentadienyl) ruthenium according to claim 1 or 2 wherein the organic solvent is an alcohol solvent.

4. The process for preparing a bis(alkylcyclopentadienyl)ruthenium according to any of claims 1 to 3 wherein zinc is present as a reducing agent in the reaction system.

5. The process for preparing a bis(alkylcyclopentadienyl)ruthenium according to any of claims 1 to 4 wherein a reaction temperature is −80 to 0° C.

6. A bis(alkylcyclopentadienyl)ruthenium prepared by the process according to any of claims 1 to 5.

7. A process for chemical vapor deposition of a ruthenium or ruthenium compound film comprising the steps of:
evaporating the bis(alkylcyclopentadienyl)ruthenium according to claim 6; and
heating the compound on a substrate to deposit ruthenium or a ruthenium compound.
